(19) United States
(12) Patent Application Publication
(10) Pub. No.: US 2008/0158655 A1
(43) Pub. Date: Jul. 3, 2008

(54) Method for Preparing a Periodically Poled Structure

(75) Inventors: Tze-Chia Lin, Hsinchu (TW); Tsai-Hau Hong, Hsinchu (TW); Ming-Hsien Chou, Hsinchu (TW)

Correspondence Address: WPAT, PC;INTELLECTUAL PROPERTY ATTORNEYS, 2030 MAIN STREET, SUITE 1300, IRVINE, CA, 92614, US

(73) Assignee: HC PHOTONICS CORP., Hsinchu (TW)

(21) Appl. No.: 11/619,021

(22) Filed: Jan. 2, 2007

(51) Int. Cl. C30B 33/04

(52) U.S. Cl. 359/326

(57) ABSTRACT

A method for preparing a periodically poled structure comprises the steps of providing a ferroelectric substrate having an upper surface and a bottom surface, forming an upper electrode including at least one first block and at least one second block on the upper surface, forming a bottom electrode including at least one third block and at least one fourth block on the bottom surface and performing a plurality of poling processes to form at least one first domain and at least one second domain in the ferroelectric substrate, wherein the first domain is formed between the first block and the third block, and the second domain is formed between the second block and the fourth block.

### BACKGROUND OF THE INVENTION

(A) Field of the Invention

The present invention relates to a method for preparing a periodically poled structure, and more particularly, to a method for preparing a periodically poled structure by performing a plurality of poling processes on two opposite surfaces of a ferroelectric substrate.

(B) Description of the Related Art

The periodically poled structure having poled domains in a ferroelectric single crystal such as lithium niobate (LiNbO₃), lithium tantalite (LiTaO₃) and potassium titanyl phosphate (KTiOPO₄) may be widely used in the optical fields such as optical storage and optical measurement. There are several methods for preparing the periodically poled structure such as the proton-exchanging method, the electron beam-scanning method, the electric voltage applying method, etc.

U.S. Pat. No. 6,002,515 discloses a method for manufacturing a polarization inversion part on a ferroelectric crystal substrate. The polarization inversion part is prepared by steps of applying a voltage in the polarization direction of the ferroelectric crystal substrate to form a polarization inversion part, conducting a heat treatment for reducing an internal electric field generated in the substrate by the applied voltage, and then reinverting polarization in a portion of the polarization inversion part by applying a reverse direction voltage against the voltage that was previously applied. In other words, the method for preparing a polarization inversion part disclosed in U.S. Pat. No. 6,002,515 requires performing the application of electric voltage twice.

One of the major factors for the realization of the above example applications depends upon the ability to pattern and fabricate the desired microstructures with the proper materials. The prior art provides a basic patterning and fabrication approach such as ferroelectric domain reversals via electrical field poling or thermal poling. However, as the desired patterned structures require finer microstructures such as shorter ferroelectric domain periods or pattern structures with aperiodic periods, the challenge of achieving the desired pattern structures becomes greater. Moreover, the conventional methods may not be applicable to the use of some materials. In addition, these methods also might encounter scalability and yield issues in the fabrication of large area patterned microstructures.

One of the key challenges in the poling of dielectric microstructures is the electric field and electric dipole interference within the body of dielectric materials during the electric field poling process. Such electric field and electric dipole interference results in non-uniform domain structures and difficulties in generating domains with short pitch (period). Additional challenges in poling of dielectric microstructures come from the scalability of the poling area. As the poling area increases, the total required poling time will also increase. The large ratio between the total amount of poling time for large area structures and the optimized poling time for each individual microstructure enhances the fabrication difficulty for generating large area and uniform microstructures.

However, as the period of the poled domains of the periodically poled structure becomes smaller, the above-mentioned conventional methods for preparing the poled domains cannot meet precision requirements.

### SUMMARY OF THE INVENTION

One aspect of the present invention provides a segmenting method for preparing a periodically poled structure

A method for preparing a periodically poled structure according to this aspect of the present invention comprises the steps of providing a ferroelectric substrate having an upper surface and a bottom surface, forming an upper electrode including at least one first block and at least one second block on the upper surface, forming a bottom electrode including at least one third block and at least one fourth block on the bottom surface and performing a plurality of poling processes to form at least one first domain and at least one second domain in the ferroelectric substrate, wherein the first domain is formed between the first block and the third block, and the second domain is formed between the second block and the fourth block.

Another aspect of the present invention provides a method for preparing a periodically poled structure comprising the steps of providing a ferroelectric substrate including an upper surface and a bottom surface, forming an upper electrode including at least one first block and at least one second block on the upper surface, forming a plurality of insulation blocks on the bottom surface, dipping the bottom surface in a conductive solution and performing a plurality of poling processes to form at least one first domain and at least one second domain in the ferroelectric substrate, wherein the first domain contacts the first block and the second domain contacts the second block.

A further aspect of the present invention provides a method for preparing a periodically poled structure comprising the steps of providing a ferroelectric substrate including an upper surface and a bottom surface, forming a plurality of insulation blocks on the bottom surface, forming a first insulation layer having at least one first aperture on the upper surface, performing a first poling process to form at least one first domain in the ferroelectric substrate, removing the first insulation layer from the upper surface, forming a second insulation layer having at least one second aperture on the upper surface and performing a second poling process to form at least one second domain in the ferroelectric substrate, wherein the first aperture exposes the first domain and the second aperture exposes the second domain.

### BRIEF DESCRIPTION OF THE DRAWINGS

The objectives and advantages of the present invention will become apparent upon reading the following description and upon reference to the accompanying drawings in which:

FIG. 1 to FIG. 9 illustrate a method for preparing a periodically poled structure according to a first embodiment of the present invention;

FIG. 10 to FIG. 18 illustrate a method for preparing a periodically poled structure according to a second embodiment of the present invention; and

FIG. 19 to FIG. 25 illustrate a method for preparing a periodically poled structure according to a third embodiment of the present invention.

### DETAILED DESCRIPTION OF THE INVENTION

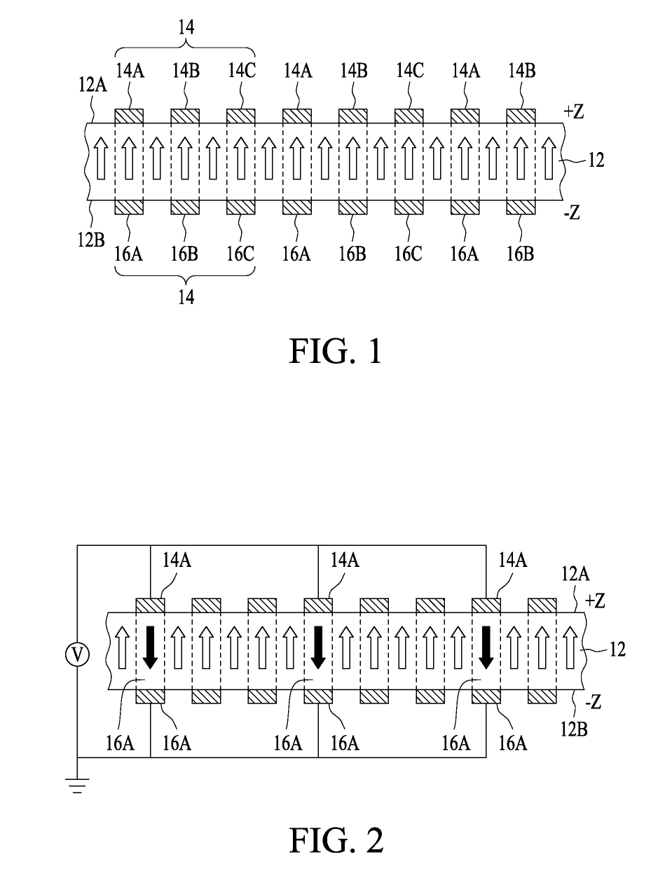

FIG. 1 to FIG. 9 illustrate a method for preparing a periodically poled structure 10 according to a first embodiment of the present invention. First, a ferroelectric substrate 12 having an upper surface 12A and a bottom surface 12B is provided, and an upper electrode 14 is formed on the upper surface 12A and a bottom electrode 16 is formed on the bottom surface 12B. The upper electrode 14 and the bottom electrode 16 can be made of metallic material. The upper electrode 14 includes first blocks 14A, second blocks 14B and fifth blocks 14C, and bottom electrode 16 includes third blocks 16A, fourth blocks 16B and sixth blocks 16C. The original polarization direction of the ferroelectric substrate 12 is from −Z to +Z, as shown by the arrows in FIG. 1.

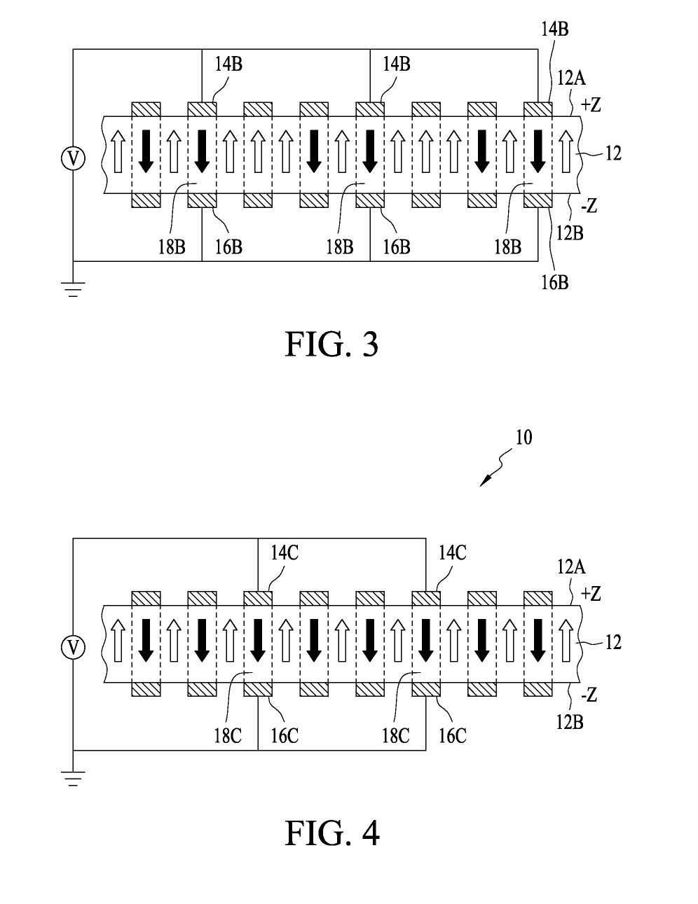

Referring to FIG. 2, a first poling process is performed by applying a predetermined voltage difference (V) between the first block 14A and the third block 16A to form at least one first domain 18A having a polarization direction opposite to the original polarization direction of the ferroelectric substrate 12. In other words, the poling process reverses the polarization direction of the first domain 18A. Subsequently, a second poling process is performed by applying the predetermined voltage difference (V) between the second block 14B and the fourth block 16B to form at least one second domain 18B having a polarization direction opposite to the original polarization direction of the ferroelectric substrate 12, as shown in FIG. 3.

Referring to FIG. 4, a third poling process is performed by applying a predetermined voltage difference (V) between the fifth block 14C and the sixth block 16C to form at least one third domain 18C having a polarization direction opposite to the original polarization direction of the ferroelectric substrate 12 and complete the periodically poled structure 10. The first domains 18A, the second domains 18B and the third domains 18C are separated by fourth domains 18D having a polarization direction the same as the original polarization direction of the ferroelectric substrate 12.

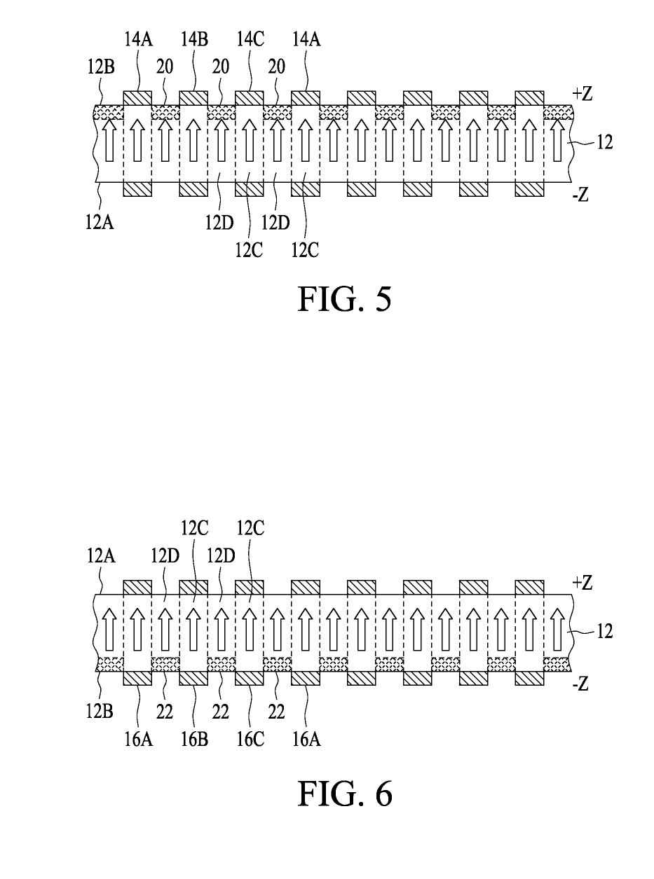

Referring to FIG. 5, the ferroelectric substrate 12 is consisting essentially of a plurality of first regions 12C and second regions 12D, and the first regions 12C are positioned between the upper electrode 14 and the bottom electrode 16. Before the poling processes are performed, the present invention may perform a doping process such as a proton exchange process to form at least one doped region such as heavy proton exchange region 20 in the upper portion of the second region 12D of the ferroelectric substrate 12, and the doped region 20 is formed between the first block 14A and the second block 14B, between the second block 14B and the fifth block 14C or between the first block 14A and the fifth block 14C. In particular, the crystal structure of the doped region 20 is different from that of the ferroelectric substrate 12. The purpose of the doping process is to change the crystal structure of the ferroelectric substrate 12, whose polarization direction cannot be reversed by the subsequent poling process so that the enlarging of the poled domains 18A, 18B and 18C due to over-poling can be inhibited.

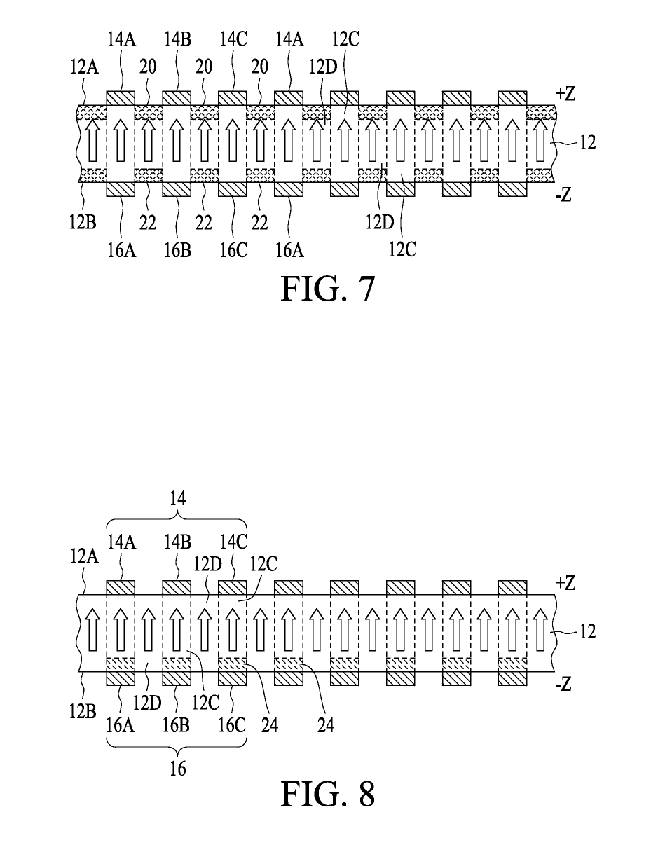

Referring to FIG. 6, the doping process may form at least one doped region 22 in the bottom portion of the second region 12D of the ferroelectric substrate 12, i.e., between the third block 16A and the fourth block 16B, between the fourth block 16B and the sixth block 16C or between the third block 16A and the sixth block 16C. In addition, the doping process may form at least one doped region 20 in the upper portion of the second region 12D of the ferroelectric substrate 12 and at least one doped region 22 in the bottom portion of the second region 12D of the ferroelectric substrate 12, as shown in FIG. 7.

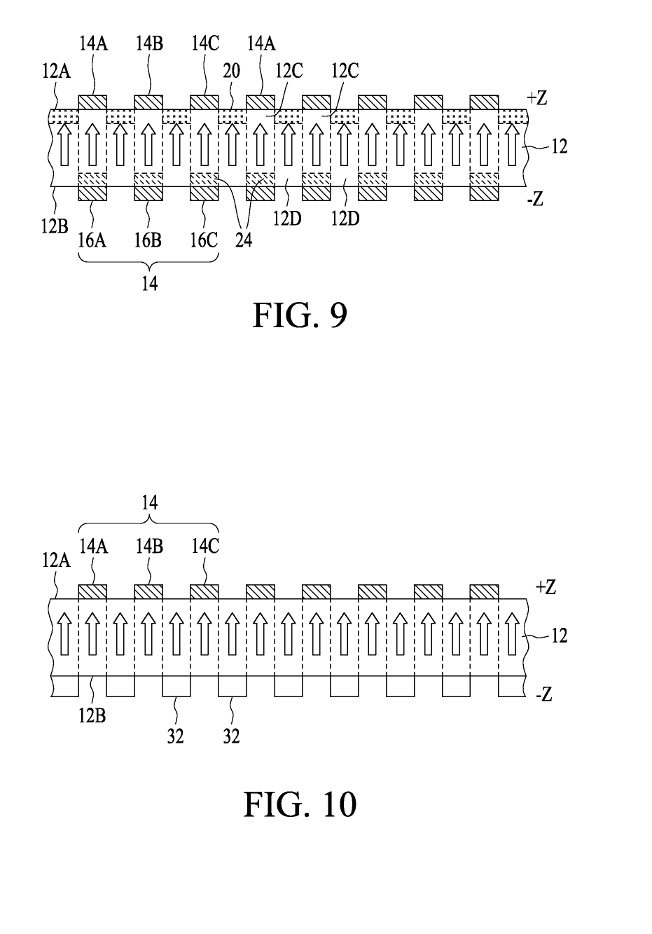

Referring to FIG. 8, before the poling processes are performed, the present invention may perform a doping process such as a proton exchange process to form at least one doped region such as a light proton exchange region—24 in the bottom portion of the first region 12C of the ferroelectric substrate 12, and the bottom electrode 16 contacts the doped region 24. The doped region 24 can increase the internal electrical field as the voltage difference (V) is applied between the upper electrode 14 and the bottom electrode 16 during the subsequent poling process, and the increased internal electrical field is contributory to the formation of the poled domains 18A, 18B and 18C. In particular, the internal electrical field generated by the doped region 24 can increase the intensity difference of the overall electrical field between the domain 12C right below the upper electrode 14 and the domain 12D between the domains 12C. In addition, before the poling processes are performed, the present invention may use the doping process to form the doped regions 20 in the upper portion of in the second region 12D of the ferroelectric substrate 12, and to the doped regions 24 in the bottom portion of the first region 12C of the ferroelectric substrate 12, as shown in FIG. 9.

FIG. 10 to FIG. 18 illustrate a method for preparing a periodically poled structure 30 according to a second embodiment of the present invention. First, a ferroelectric substrate 12 having an upper surface 12A and a bottom surface 12B is provided, and an upper electrode 14 is formed on the upper surface 12A and a plurality of insulation blocks 32 is formed on the bottom surface 12B. The insulation blocks 32 can be made of silicon oxide. The upper electrode 14 includes first blocks 14A, second blocks 14B and fifth blocks 14C. The original polarization direction of the ferroelectric substrate 12 is from −Z to +Z, as shown by the arrows in FIG. 10.

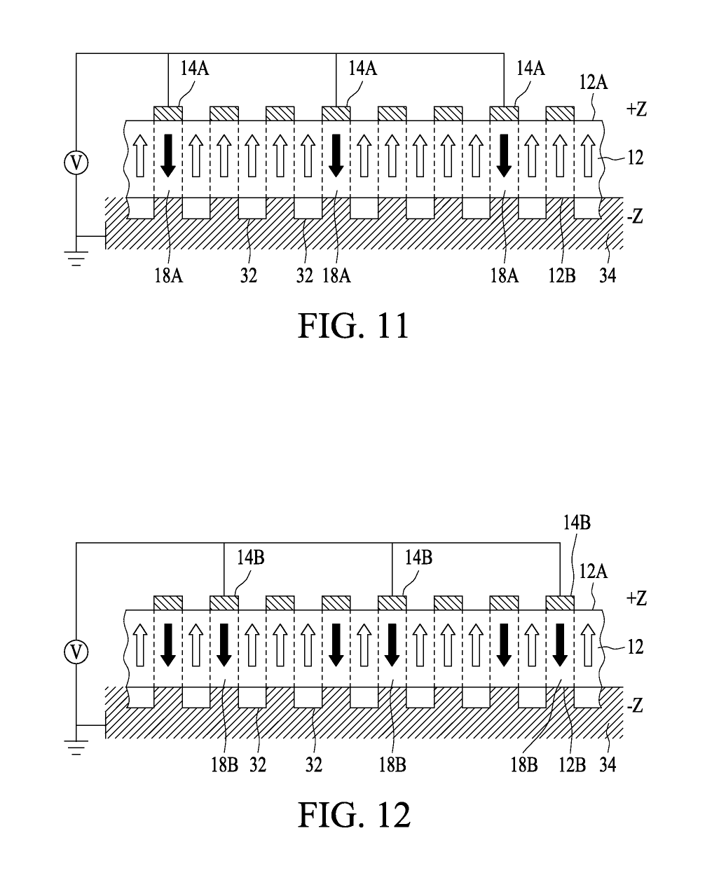

Referring to FIG. 11, the bottom surface 12B is dipped in a conductive solution 34, and a first poling process is performed by applying a predetermined voltage difference (V) between the first block 14A and the conductive solution 34 to form at least one first domain 18A contacting the first block 14A. The first domain 18A has a polarization direction opposite to the original polarization direction of the ferroelectric substrate 12. In other words, the poling process reverses the polarization direction of the first domain 18A. Subsequently, a second poling process is performed by applying the predetermined voltage difference (V) between the second block 14B and the conductive solution 34 to form at least one second domain 18B having a polarization direction opposite to the original polarization direction of the ferroelectric substrate 12, as shown in FIG. 12.

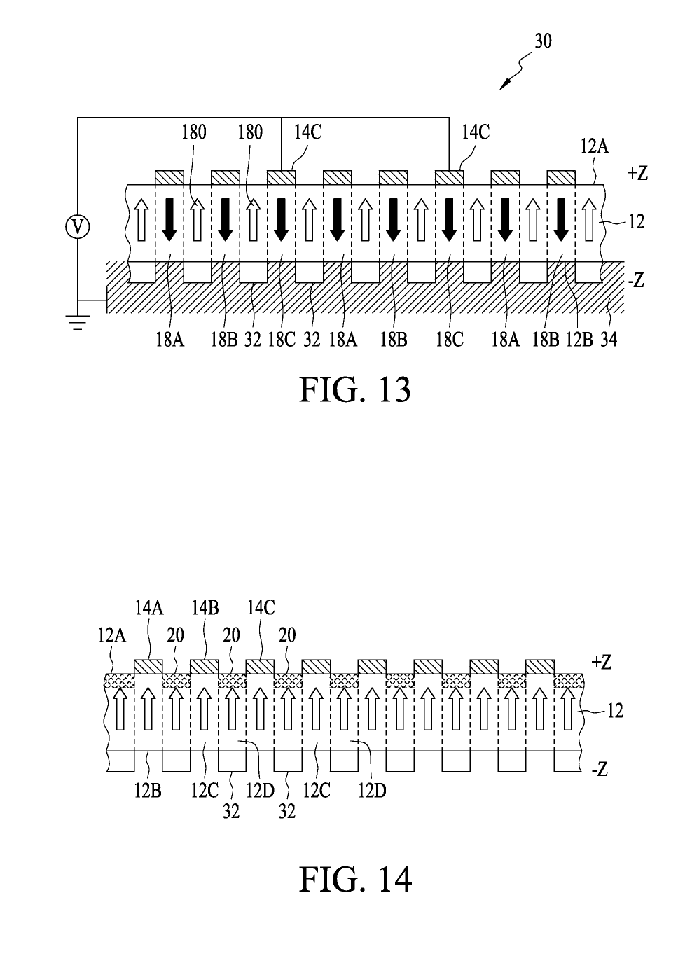

Referring to FIG. 13, a third poling process is performed by applying a predetermined voltage difference (V) between the fifth block 14C and the conductive solution 34 to form at least one third domain 18C having a polarization direction opposite to the original polarization direction of the ferroelectric substrate 12 to complete the periodically poled structure 30. The first domains 18A, the second domains 18B and the third domains 18C are separated by fourth domains 18D having a polarization direction the same as the original polarization direction of the ferroelectric substrate 12.

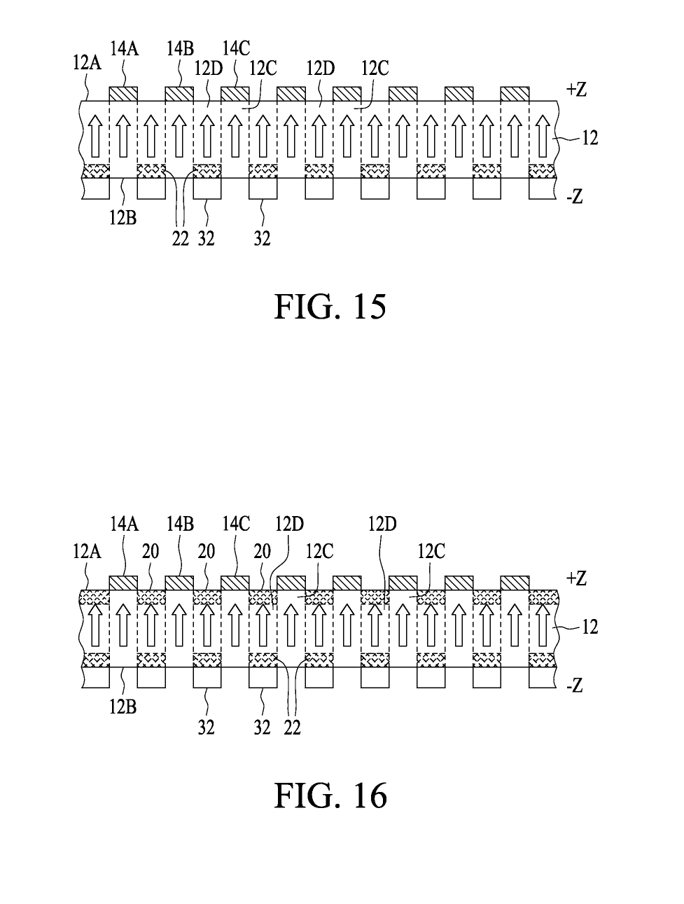

Referring to FIG. 14, before the poling processes are performed, the present invention may perform a doping process such as a proton exchange process to form at least one doped region (heavy proton exchange region) 20 in the upper portion of the second region 12D of the ferroelectric substrate 12, i.e., the doped region 20 can be formed between the first block 14A and the second block 14B, between the second block 14B and the fifth block 14C or between the first block 14A and the fifth block 14C. The purpose of the doping process is to change the crystal structure of the ferroelectric substrate 12 and the polarization direction of the doped region 20 cannot be reversed by the subsequent poling process so that the enlarging of the poled domains 18A, 18B and 18C due to over-poling can be inhibited. In addition, the doping process may form at least one doped region 22 in the bottom portion of the second region 12D, i.e., the doped region 22 contacts the insulation blocks 32, as shown in FIG. 15. Furthermore, the doping process may form at least one doped region 20 in the upper portion of the second region 12D of the ferroelectric substrate 12 and at least one doped region 22 in the bottom portion of the second region 12D of the ferroelectric substrate 12, as shown in FIG. 16.

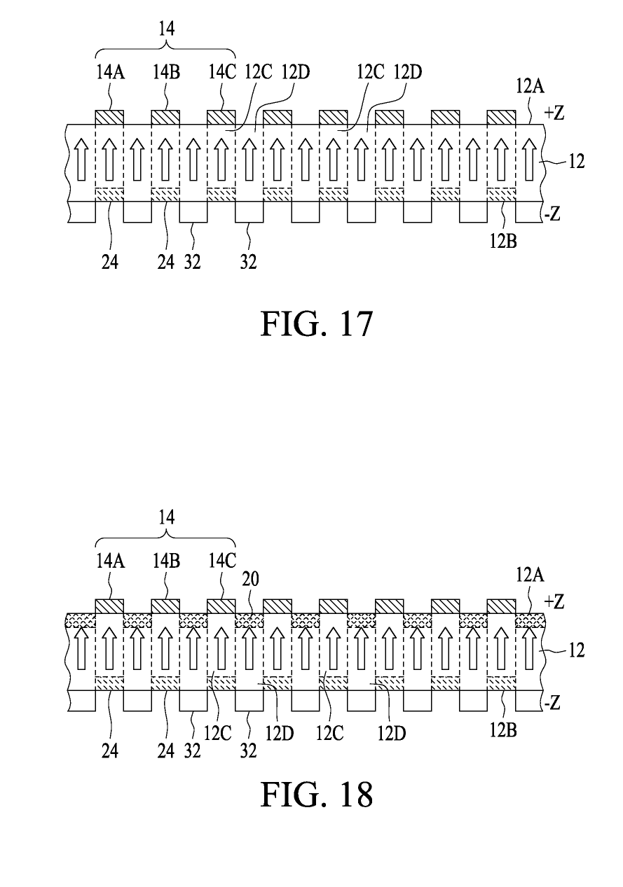

Referring to FIG. 17, before the poling processes are performed, the present invention may perform a doping process to form at least one doped region (light proton exchange region) 24 in the bottom portion of first region 12C of the ferroelectric substrate 12, i.e., the doped region 24 is formed between the insulation blocks 34. The doped region 24 can increase the internal electrical field as the voltage difference (V) is applied between the upper electrode 14 and the bottom electrode 16 during the subsequent poling process, and the increased internal electrical field is contributory to the formation of the poled domains 18A, 18B and 18C. In addition, before the poling processes are performed, the present invention may use the doping process to form the doped regions 20 in the upper portion of the second region 12D of the ferroelectric substrate 12, and to the doped regions 24 in the bottom portion of the first region 12C of the ferroelectric substrate 12, as shown in FIG. 18.

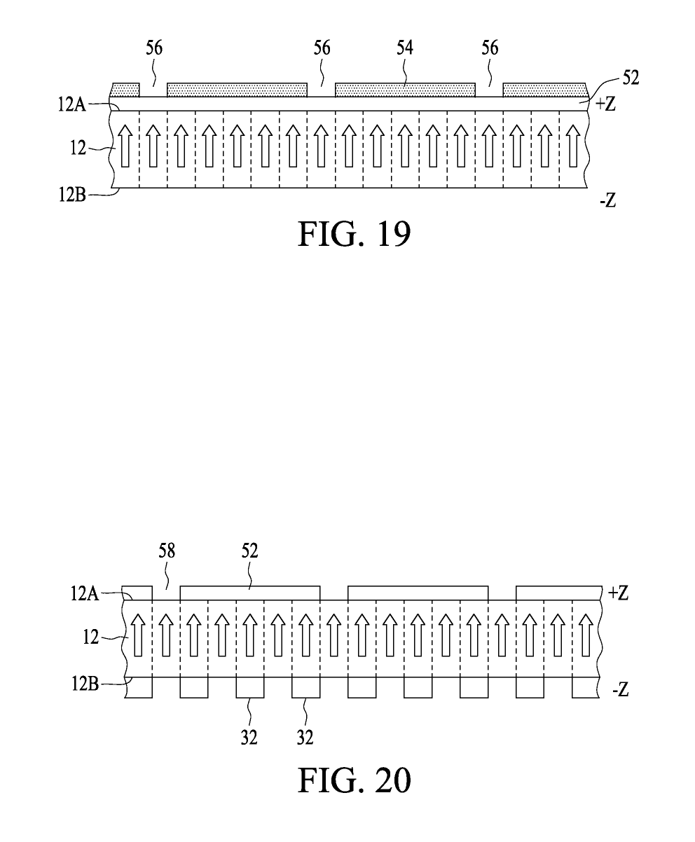

FIG. 19 to FIG. 25 illustrate a method for preparing a periodically poled structure 50 according to a third embodiment of the present invention. First, a ferroelectric substrate 12 having an upper surface 12A and a bottom surface 12B is provided, and a deposition process is performed to form an insulation layer 52 on the upper surface 12A. The insulation layer 52 can be made of silicon oxide, and the original polarization direction of the ferroelectric substrate 12 is from −Z to +Z. A lithographic process is performed to form an etching mask 54 having at least one opening 56 on the insulation layer 52, and an etching process is then performed to remove a portion of the insulation layer 52 not covered by the opening 56 to form at least one aperture 58 in the insulation layer 52. Subsequently, the etching mask 54 is removed, and the same processes are performed to form a plurality of insulation blocks 32 on the bottom surface 12B, as shown in FIG. 20.

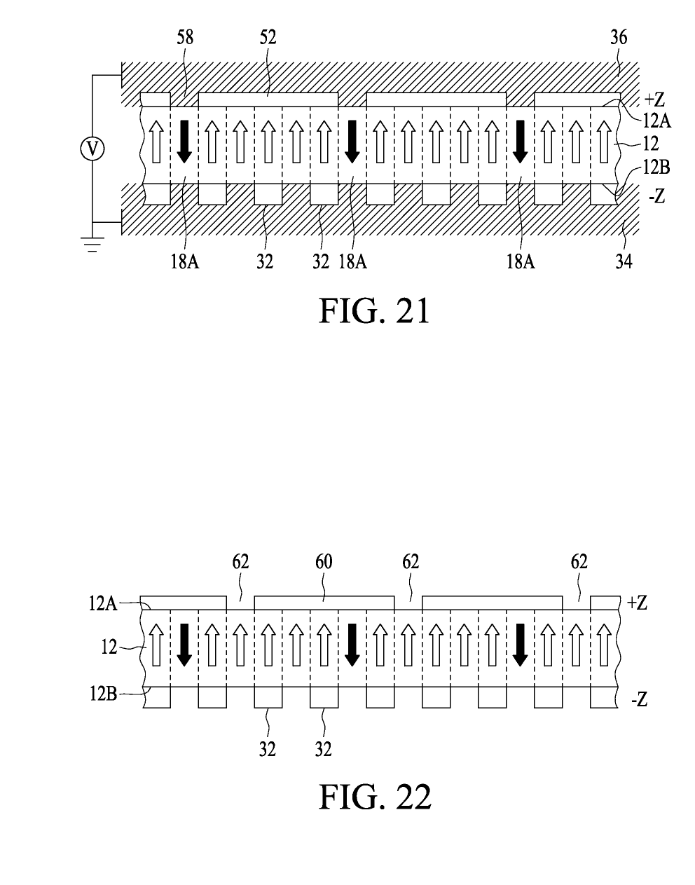

Referring to FIG. 21, the upper surface 12A is dipped in a conductive solution 36 and the bottom surface 12B is dipped in a conductive solution 34, and a predetermined voltage difference (V) is applied between the conductive solution 36 and the conductive solution 34 to perform a first poling process to form at least one first domain 18A in the ferroelectric substrate 12. The first domain 18A has a polarization direction opposite to the original polarization direction of the ferroelectric substrate 12. In other words, the poling process reverses the polarization direction of the first domain 18A. In particular, the aperture 58 exposes the first domain 18A.

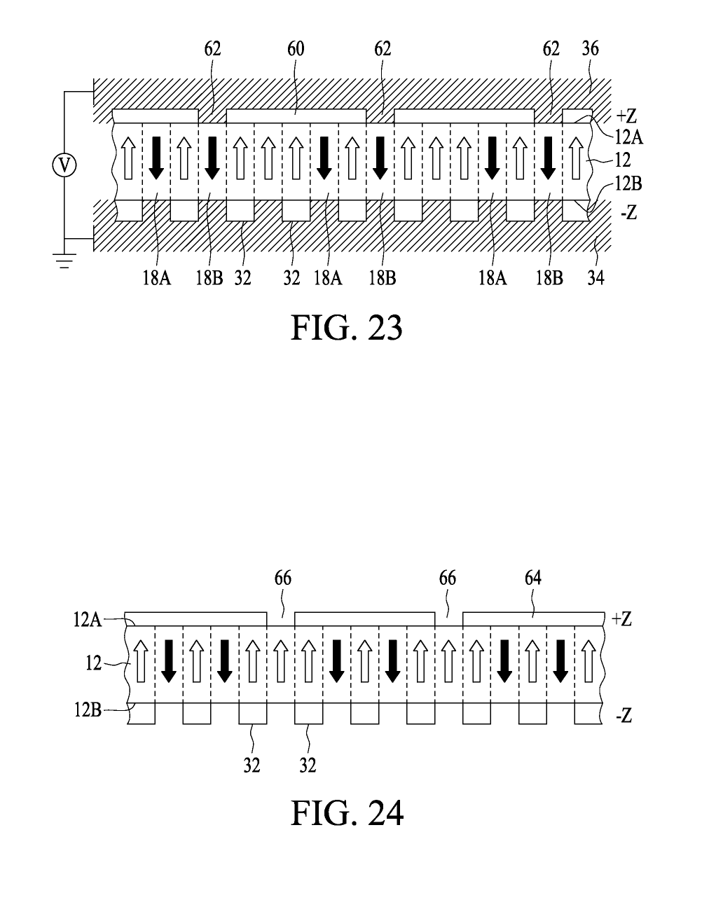

Referring to FIG. 22, the insulation layer 52 is removed from the upper surface 12A, and the processes shown in FIG. 19 are performed to form an insulation layer 60 having at least one aperture 62 on the upper surface 12A. Subsequently, the upper surface 12A is dipped in the conductive solution 36 and the bottom surface 12B is dipped in the conductive solution 34, and a predetermined voltage difference (V) is applied between the conductive solution 36 and the conductive solution 34 to perform a second poling process to form at least one second domain 18B in the ferroelectric substrate 12, as shown in FIG. 23. In particular, the aperture 62 exposes the second domain 18B.

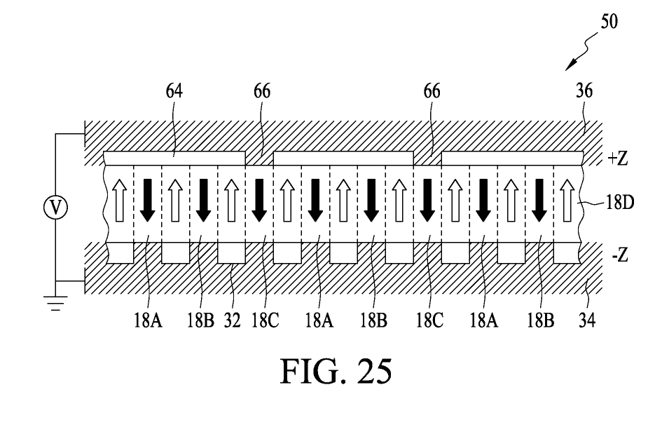

Referring to FIG. 24, the insulation layer 60 is removed from the upper surface 12A, and the processes shown in FIG. 19 are performed to form an insulation layer 64 having at least one aperture 66 on the upper surface 12A. Subsequently, the upper surface 12A is dipped in the conductive solution 36 and the bottom surface 12B is dipped in the conductive solution 34, and a predetermined voltage difference (V) is applied between the conductive solution 36 and the conductive solution 34 to perform a third poling process to form at least one third domain 18C in the ferroelectric substrate 12 and complete the periodically poled structure 50, as shown in FIG. 25. In particular, the aperture 66 exposes the third domain 18C, and the first domains 18A, the second domains 18B and the third domains 18C are separated by fourth domains 18D.

The above-described embodiments of the present invention are intended to be illustrative only. Numerous alternative embodiments may be devised by those skilled in the art without departing from the scope of the following claims.

What is claimed is:

1. A method for preparing a periodically poled structure, comprising the steps of:
providing a ferroelectric substrate having an upper surface and a bottom surface;
forming an upper electrode including at least one first block and at least one second block on the upper surface;
forming a bottom electrode including at least one third block and at least one fourth block on the bottom surface; and
performing a plurality of poling processes to form at least one first domain and at least one second domain in the ferroelectric substrate, the first domain being formed between the first block and the third block, and the second domain being formed between the second block and the fourth block.

2. The method for preparing a periodically poled structure as claimed in claim 1, wherein the step of performing a plurality of poling processes includes:
performing a first poling process by applying a predetermined voltage difference between the first block and the third block to form the first domain; and
performing a second poling process by applying a predetermined voltage difference between the second block and the fourth block to form the second domain.

3. The method for preparing a periodically poled structure as claimed in claim 2, wherein the upper electrode further includes at least one fifth block and the bottom electrode further includes at least one sixth block, and the step of performing a plurality of poling processes further includes performing a third poling process by applying the predetermined voltage between the fifth block and the sixth block to form at least one third domain in the ferroelectric substrate.

4. The method for preparing a periodically poled structure as claimed in claim 1, further comprising a step of changing the crystal structure of a portion of the ferroelectric substrate.

5. The method for preparing a periodically poled structure as claimed in claim 4, wherein the crystal structure of a portion of the ferroelectric substrate is changed by performing a doping process.

6. The method for preparing a periodically poled structure as claimed in claim 1, further comprising the steps of:
forming at least one first doped region in the ferroelectric substrate, wherein the first doped region is formed between the first block and the second block; and
forming at least one second doped region in the ferroelectric substrate, wherein the second doped region is formed between the third block and the fourth block.

7. The method for preparing a periodically poled structure as claimed in claim 6, wherein the first doped region and the second doped region are formed by at least one doping process.

8. The method for preparing a periodically poled structure as claimed in claim 1, further comprising a step of performing a doping process to form at least one doped region in the ferroelectric substrate, wherein the bottom electrode contacts the doped region.

9. The method for preparing a periodically poled structure as claimed in claim 1, further comprising the steps of:
forming at least one first doped region in the ferroelectric substrate, wherein the first doped region is formed between the first block and the second block; and
forming at least one second doped region in the ferroelectric substrate, wherein the bottom electrode contacts the second doped region.

10. The method for preparing a periodically poled structure as claimed in claim 9, wherein the first doped region and the second doped region are formed by at least one doping process.

11. A method for preparing a periodically poled structure, comprising the steps of:
providing a ferroelectric substrate including an upper surface and a bottom surface;
forming an upper electrode including at least one first block and at least one second block on the upper surface;
forming a plurality of insulation blocks on the bottom surface;
dipping the bottom surface in a conductive solution; and
performing a plurality of poling processes to form at least one first domain and at least one second domain in the ferroelectric substrate, the first domain contacting the first block, and the second domain contacting the second block.

12. The method for preparing a periodically poled structure as claimed in claim 11, wherein the step of performing a plurality of poling processes includes:
performing a first poling process by applying a predetermined voltage difference between the first block and the conductive solution to form the first domain in the ferroelectric substrate; and
performing a second poling process by applying the predetermined voltage difference between the second block and the conductive solution to form the second domain in the ferroelectric substrate.

13. The method for preparing a periodically poled structure as claimed in claim 11, wherein the upper electrode further includes at least one third block, and the step of performing a plurality of poling processes further includes performing a third poling process by applying a predetermined voltage to the third block and the conductive solution to form at least one third domain in the ferroelectric substrate.

14. The method for preparing a periodically poled structure as claimed in claim 11, further comprising a step of changing the crystal structure of a portion of the ferroelectric substrate.

15. The method for preparing a periodically poled structure as claimed in claim 14, wherein the crystal structure of a portion of the ferroelectric substrate is changed by performing a doping process.

16. The method for preparing a periodically poled structure as claimed in claim 11, further comprising the steps of:
forming at least one first doped region in the ferroelectric substrate, and the first insulation region being formed between the first block and the second block; and
forming at least one second doped region in the ferroelectric substrate, and the first doped region contacting the insulation block.

17. The method for preparing a periodically poled structure as claimed in claim 16, wherein the first doped regions and the second doped regions are formed by at least one doping process.

18. The method for preparing a periodically poled structure as claimed in claim 11, further comprising a step of performing a doping process to form at least one doped region in the ferroelectric substrate, and the doped region being formed between the insulation blocks.

19. The method for preparing a periodically poled structure as claimed in claim 11, further comprising the steps of:
forming at least one first doped region in the ferroelectric substrate, and the first doped region being formed between the first block and the second block; and
forming at least one second doped region in the ferroelectric substrate, and the second doped region being formed between the insulation blocks.

20. The method for preparing a periodically poled structure as claimed in claim 16, wherein the first doped region and the second doped region are formed by at least one doping process.

21. A method for preparing a periodically poled structure, comprising the steps of:
providing a ferroelectric substrate including an upper surface and a bottom surface;
forming a first insulation layer having at least one first aperture on the upper surface;
performing a first poling process to form at least one first domain in the ferroelectric substrate, and the first aperture exposing the first domain;
removing the first insulation layer from the upper surface;
forming a second insulation layer having at least one second aperture on the upper surface; and
performing a second poling process to form at least one second domain in the ferroelectric substrate, and the second aperture exposing the second domain.

22. The method for preparing a periodically poled structure as claimed in claim 21, wherein the step of forming at least one first insulation layer having at least one first aperture on the upper surface includes:
performing a deposition process to form the first insulation layer on the upper surface;
forming a mask having at least one opening on the first insulation layer; and
removing a portion of the first insulation layer not covered by the opening to form the first aperture of the first insulation layer.

23. The method for preparing a periodically poled structure as claimed in claim 22, wherein the step of forming a mask having at one opening on the first insulation layer includes performing at least one lithographic process.

24. The method for preparing a periodically poled structure as claimed in claim 21, wherein the step of performing a first poling processes includes:
dipping the upper surface in a first conductive solution and the bottom surface in a second conductive solution; and
applying a predetermined voltage difference between the first conductive solution and the second conductive solution to form the first domains in the ferroelectric substrate.

25. The method for preparing a periodically poled structure as claimed in claim 21, further comprising the steps of:
removing the second insulation layer from the upper surface;
forming a third insulation layer having at least one third aperture on the upper surface; and
performing a third poling process to form at least one third domains in the ferroelectric substrate, and the third aperture exposing the third domain.
